(19) United States
(12) Patent Application Publication
(10) Pub. No.: US 2023/0245869 A1
(43) Pub. Date: Aug. 3, 2023

(54) SUBSTRATE PROCESSING APPARATUS, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventors: Tetsuaki INADA, Toyama (JP); Takeshi YASUI, Toyama (JP)

(21) Appl. No.: 18/087,216

(22) Filed: Dec. 22, 2022

(30) Foreign Application Priority Data
Jan. 28, 2022 (JP) 2022-011869

(51) Int. Cl. H01J 37/32

(52) U.S. Cl. CPC H01J 37/32724; H01J 2237/20235; H01J 2237/338; H01L 21/02164

(57) ABSTRACT

According to the present disclosure, there is provided a technique capable of efficiently heating a substrate with a light emitted from a lamp heater. According to one aspect of the technique of the present disclosure, there is provided a substrate processing apparatus including: a process vessel at least a part of which is made of opaque quartz; a substrate mounting table provided in the process vessel or in a processing space communicating with an inside of the process vessel; a lamp heater provided at a position facing a substrate placing surface of the substrate mounting table; and a plasma generator provided at an outer periphery of the process vessel and configured to excite a gas in the process vessel by a plasma.

### CROSS REFERENCE TO RELATED APPLICATIONS

This non-provisional U.S. patent application is based on and claims priority under 35 U.S.C. § 119 of Japanese Patent Application No. 2022-011869 on Jan. 28, 2022, in the Japanese Patent Office, the entire contents of which are hereby incorporated by reference.

### TECHNICAL FIELD

The present disclosure relates to a substrate processing apparatus, a method of manufacturing a semiconductor device and a non-transitory computer-readable recording medium.

### BACKGROUND

According to some related arts, a substrate processing apparatus is capable of performing a substrate processing such as a modification process of modifying a surface of a pattern formed on a substrate by using a plasma-excited process gas.

In the substrate processing as described above, the substrate may be efficiently heated by using a heater such as a lamp heater. For example, in the substrate processing apparatus of according to the related arts described above, a reflective material is provided so as to surround an outer periphery of a process vessel of the substrate processing apparatus. Thereby, an infrared light emitted from the heater is capable of being reflected by the reflective material.

### SUMMARY

According to the present disclosure, there is provided a technique capable of efficiently heating a substrate with a light emitted from a lamp heater

According to an aspect the technique of the present disclosure, there is provided a substrate processing apparatus including: a process vessel at least a part of which is made of opaque quartz; a substrate mounting table provided in the process vessel or in a processing space communicating with an inside of the process vessel; a lamp heater provided at a position facing a substrate placing surface of the substrate mounting table; and a plasma generator provided at an outer periphery of the process vessel and configured to excite a gas in the process vessel by a plasma.

### BRIEF DESCRIPTION OF THE DRAWINGS

FIG. 1 is a diagram schematically illustrating a cross-section of a substrate processing apparatus according to one or more embodiments of the present disclosure.

FIG. 2 is a diagram schematically illustrating a principle of generating a plasma in the substrate processing apparatus according to the embodiments of the present disclosure.

FIG. 3 is a diagram schematically illustrating a cross-section of a lower end portion of a process vessel (more specifically, an upper vessel) of the substrate processing apparatus according to the embodiments of the present disclosure.

FIG. 4 is a diagram schematically illustrating a cross-section of an upper end portion of the process vessel (more specifically, the upper vessel) of the substrate processing apparatus according to the embodiments of the present disclosure.

FIG. 5 is a block diagram schematically illustrating a configuration of a controller (control structure) and related components of the substrate processing apparatus according to the embodiments of the present disclosure.

FIG. 6 is a flow chart schematically illustrating a substrate processing according to the embodiments of the present disclosure.

### DETAILED DESCRIPTION

### Embodiments of Present Disclosure

Hereinafter, one or more embodiments (also simply referred to as “embodiments”) of the technique of the present disclosure will be described in detail with reference to the drawings. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

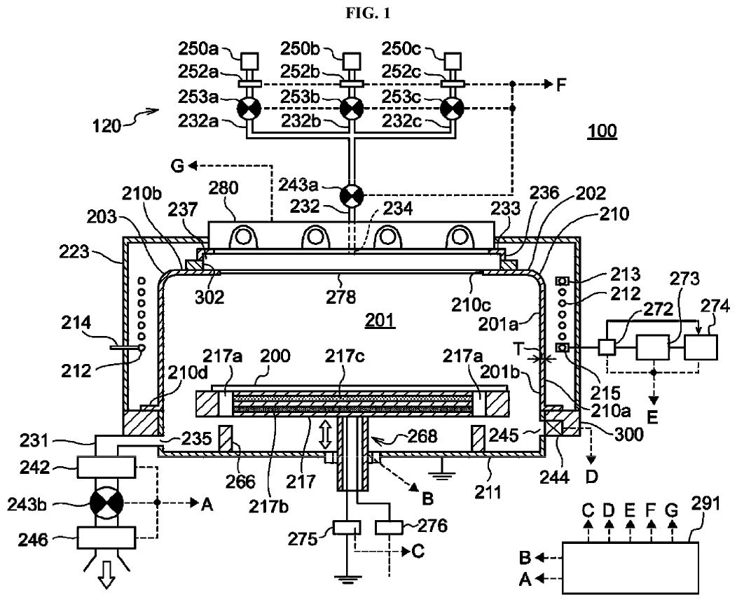

Hereinafter, a configuration of a substrate processing apparatus 100 according to the present embodiments will be described with reference to FIGS. 1 through 5. The substrate processing apparatus 100 according to the present embodiments is configured to perform an oxidation process on a base of a substrate 200 or on a film formed on a surface of the substrate 200.

### <Process Chamber>

The substrate processing apparatus 100 includes a process furnace 202 in which the substrate 200 is processed by a plasma. The process furnace 202 is provided with a process vessel 203 by which a process chamber 201 is defined. The process vessel 203 includes a dome-shaped upper vessel 210 serving as a first vessel and a bowl-shaped lower vessel 211 serving as a second vessel. By covering the lower vessel 211 with the upper vessel 210, the process chamber 201 is defined.

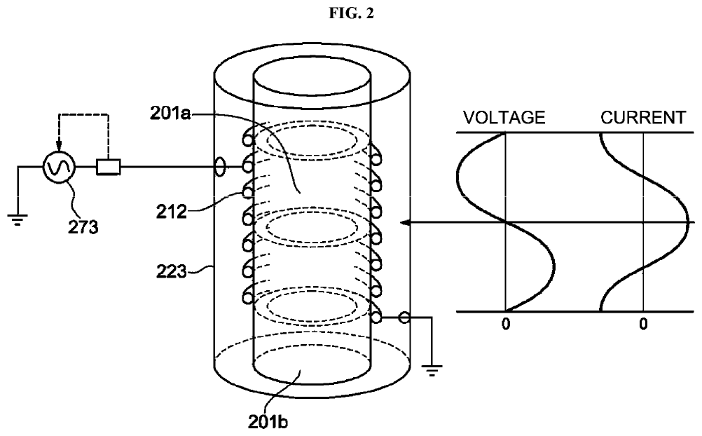

As shown in FIG. 2, the process chamber 201 includes a plasma generation space 201a and a substrate processing space 201b. The plasma generation space 201a refers to a space in which a resonance coil 212 (which is a coil serving as an electrode) is provided around the space, and the plasma is generated in the plasma generation space 201a. Specifically, the plasma generation space 201a refers to a space in the process chamber 201 above a lower end of the resonance coil 212 and below an upper end of the resonance coil 212. The substrate processing space 201b refers to a space that communicates with the plasma generation space 201a and in which the substrate 200 is processed. Specifically, the substrate processing space 201b refers to a space in which the substrate 200 is processed by using the plasma, for example, a space below the lower end of the resonance coil 212. According to the present embodiments, a diameter of the plasma generation space 201a in a horizontal direction is substantially the same as a diameter of the substrate processing space 201b in the horizontal direction. A configuration constituting the plasma generation space 201a may also be referred to as a “plasma generation chamber”, and a configuration constituting the substrate processing space 201b may also be referred to as a “substrate process vessel”. Further, the plasma generation space 201a may also be referred to as a “plasma generation region” in the process chamber 201, and the substrate processing space 201b may also be referred to as a “substrate processing region” in the process chamber 201.

The upper vessel 210 is an example of a part of the process vessel 203 in the embodiments of the present disclosure. In addition, in the flowing descriptions, the upper vessel 210 alone may also be referred to as “the process vessel 203”. As shown in FIGS. 1, 3 and 4, the upper vessel 210 includes a side wall 210a of a cylindrical shape and a ceiling 210b. The ceiling 210b is a portion that protrudes radially inward from an upper end portion of the side wall 210a. An opening 210c is provided in a central portion of the ceiling 210b. A transmission window 278 serving as a light transmission window made of a transparent material is provided at the opening 210c. The transmission window 278 is arranged so as to face an upper surface of a susceptor 217 described later.

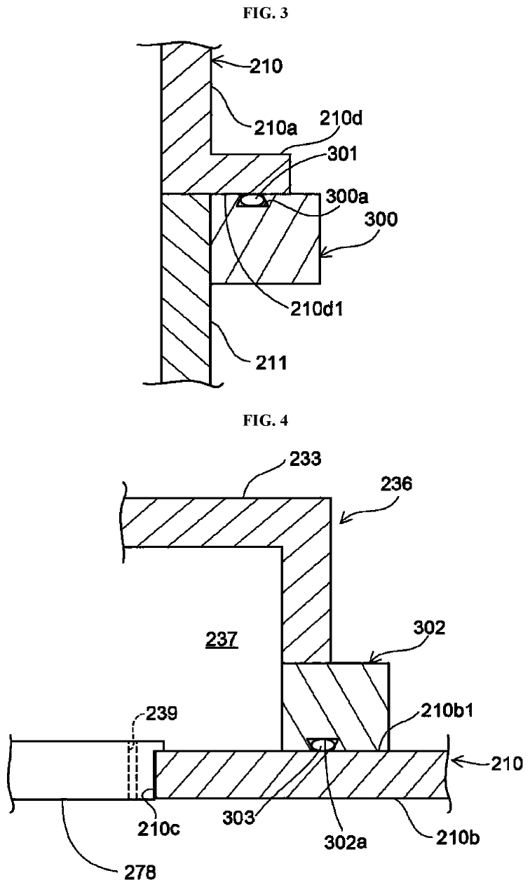

As shown in FIGS. 1 and 3, a flange 210d is provided at a lower end portion of the upper vessel 210. The flange 210d is a portion that protrudes radially outward from a lower end portion of the side wall 210a. The flange 210d is provided in an annular shape along a circumferential direction of the side wall 210a. A manifold 300 of an annular shape is attached to the flange 210d from below. Specifically, for example, the flange 210d and the manifold 300 are fastened and fixed by a screw (not shown) such that an upper surface of the manifold 300 made of a metal material is in contact with a lower surface of the flange 210d. An O-ring 301 made of a resin and serving as a seal is arranged on the upper surface of the manifold 300. The O-ring 301 is accommodated in an annular groove 300a provided at the upper surface of the manifold 300. Further, when the flange 210d and the manifold 300 are attached (that is, fixed by fastening), the O-ring 301 is in close contact with both of the lower surface of the flange 210d and the upper surface of the manifold 300. Further, a material of the O-ring 301 is not particularly limited to the resin as long as an elastic body with a heat resistance is used as the O-ring 301. For example, an O-ring made of a fluorine-based resin may be used as the O-ring 301.

As shown in FIGS. 1 and 4, the ceiling 210b provided with the opening 210c is a portion that extends along the circumferential direction of the side wall 210a and that protrudes radially inward from the upper end portion of the side wall 210a. That is, the ceiling 210b may also be referred to as a flange provided at an upper end portion of the upper vessel 210. A manifold 302 of an annular shape is attached to the ceiling 210b from above. Specifically, for example, the ceiling 210b and the manifold 302 are fastened and fixed by a screw (not shown) such that an upper surface of the ceiling 210b is in contact with a lower surface of the manifold 302. An O-ring 303 made of a resin and serving as a seal is arranged on the lower surface of the manifold 302. The O-ring 303 is accommodated in an annular groove 302a provided at the lower surface of the manifold 302. Further, when the ceiling 210b and the manifold 302 are attached (that is, fixed by fastening), the O-ring 303 is in close contact with both of the upper surface of the ceiling 210b and the lower surface of the manifold 302. Further, a material of the O-ring 303 is not particularly limited to the resin as long as an elastic body with a heat resistance is used as the O-ring 303. For example, an O-ring made of a fluorine-based resin may be used as the O-ring 303.

Further, the upper vessel 210 includes a portion made of opaque quartz. In other words, at least a part of the upper vessel 210 is made of the opaque quartz. The opaque quartz constituting the upper vessel 210 is capable of reflecting a light (electromagnetic wave), more specifically, is capable of reflecting the light emitted (or radiated) from a lamp heater 280 described later. That is, the opaque quartz is a material whose reflectance is high with respect to the light emitted from the lamp heater 280.

A portion of the process vessel 203, which corresponds to a range from the upper end to the lower end of the resonance coil 212 that constitutes a plasma generator, is made of the opaque quartz. Specifically, a portion of the upper vessel 210, which corresponds to the plasma generation space 201a (that is, a portion that constitutes the plasma generation space 201a), is made of the opaque quartz. According to the present embodiments, at least a part of the side wall 210a corresponds to the portion that constitutes the plasma generation space 201a.

At least a part of the ceiling 210b of the upper vessel 210 is made of the opaque quartz. Specifically, a joint surface 210b1 of the ceiling 210b (the upper surface of the ceiling 210b) that is attached to the manifold 302 is made of the opaque quartz.

At least a part of the flange 210d of the upper vessel 210 is made of the opaque quartz. Specifically, a joint surface 210d1 of the flange 210d (the lower surface of the flange 210d) that is attached to the manifold 300 is made of the opaque quartz.

It is preferable that an entirety of the sidewall 210a of the upper vessel 210 is made of the opaque quartz. It is more preferable that an entirety of the ceiling 210b and an entirety of the flange 210d of the upper vessel 210 are made of the opaque quartz. That is, from a viewpoint of reflecting the light, it is most preferable that an entirety of the upper vessel 210 is made of the opaque quartz. Thus, for example, the entirety of the upper vessel 210 according to the present embodiments is made of the opaque quartz.

A process of reducing a surface roughness is performed on a portion of an inner surface of the upper vessel 210 (that is, an inner surface of the side wall 210a), which is made of the opaque quartz. Specifically, as the process of reducing the surface roughness, for example, a baking finish process is performed on at least a portion of the inner surface of the upper vessel 210 corresponding to the plasma generation space 201a. By performing the baking finish process, it is possible to reduce the surface roughness caused by air bubbles contained in the opaque quartz.

Further, the process of reducing the surface roughness may be performed on the joint surface 210d1 of the flange 210d. Specifically, as the process of reducing the surface roughness, for example, the baking finish process is performed on the joint surface 210d1 of the flange 210d.

Further, the process of reducing the surface roughness may be performed on the joint surface 210b1 of the ceiling 210b. Specifically, as the process of reducing the surface roughness, for example, the baking finish process is performed on the joint surface 210b1 of the ceiling 210b.

For example, the lower vessel 211 is made of a material such as aluminum (Al). A gate valve 244 is provided on a lower portion of a side wall of the lower vessel 211.

### <Susceptor>

As shown in FIG. 1, the susceptor 217 serving as a substrate mounting table on which the substrate 200 is placed is provided at a center of a bottom portion of the process chamber 201. The susceptor 217 is provided in the process chamber 201 and below the resonance coil 212. Specifically, the susceptor 217 is arranged in the substrate processing space 201b inside the process chamber 201.

A susceptor heater 217b is integrally embedded in the susceptor 217. When an electric power is supplied to the susceptor heater 217b, the susceptor heater 217b is capable of heating the substrate 200.

The susceptor 217 is electrically insulated from the lower vessel 211. An impedance adjusting electrode 217c is provided in the susceptor 217 in order to further improve a uniformity of a density of the plasma generated on the substrate 200 placed on the susceptor 217. Further, the impedance adjustment electrode 217c is grounded via a variable impedance regulator 275 serving as an impedance adjusting structure.

A susceptor elevator 268 including a driver (which is a driving structure) capable of elevating and lowering the susceptor 217 is provided at the susceptor 217. In addition, a plurality of through-holes 217a are provided at the susceptor 217, and a plurality of substrate lift pins 266 are provided at a bottom surface of the lower vessel 211 at locations corresponding to the plurality of first through-holes 217a. When the susceptor 217 is lowered by the susceptor elevator 268, the substrate lift pins 266 are configured to pass through the through-holes 217a. Further, an elevating and lowering operation of the susceptor 217 by the driver of the susceptor elevator 268 is controlled by a controller 291 described later. The controller 291 is configured to be capable of controlling the driver of the susceptor elevator 268 such that the substrate 200 is located below the plasma generation space 201a when the substrate 200 placed on the upper surface (which is an example of a substrate placing surface) of the susceptor 217 is processed.

A substrate mounting structure according to the present embodiments is constituted mainly by the susceptor 217, the susceptor heater 217b and the impedance adjusting electrode 217c.

### <Lamp Heater>

The lamp heater 280 serving as a heater is provided at a position facing the upper surface of the susceptor 217 in the process chamber 201. The lamp heater 280 is arranged above the process chamber 201, that is, outside the transmission window 278 provided at the upper vessel 210. Further, the lamp heater 280 is configured to emit (or radiate) the light from an outer side (that is, an upper side) of the transmission window 278 at an upper portion of the process chamber 201 to the substrate 200 accommodated in the process chamber 201 to heat the substrate 200. Specifically, the lamp heater 280 is attached to a central portion of a lid 233. An outer peripheral portion of the lid 233 is attached to the manifold 300. That is, the lid 233 to which the lamp heater 280 is attached is joined to the upper vessel 210 via the manifold 300. A seal (not shown) is arranged between the lid 233 and the manifold 300.

For example, the lamp heater 280 is set so as to emit the light of peak wavelength of 5 μm or less. Further, it is preferable that a lamp heater capable of emitting a light of peak wavelength of 3 μm or less is used as the lamp heater 280. It is preferable that a lamp heater capable of emitting a near-infrared light (that is, a light of peak wavelength of 800 nm to 1,300 nm, more preferably, a light of peak wavelength of 1,000 nm) is used as the lamp heater 280. In addition, for example, a halogen heater may be used as the lamp heater 280.

### <Gas Supplier>

A gas supplier 120 through which a process gas is supplied into the process vessel 203 is configured as follows.

A gas supply head 236 is provided above the process chamber 201, that is, on an upper portion of the upper vessel 210. The gas supply head 236 is provided with the lid 233 of a cap shape, a gas inlet port 234, a buffer chamber 237 and a gas outlet port 239. The gas supply head 236 is configured to supply the process gas such as a reactive gas into the process chamber 201. The gas outlet port 239 is provided in the transmission window 278.

A downstream end of an oxygen-containing gas supply pipe 232a through which an oxygen-containing gas is supplied, a downstream end of a hydrogen-containing gas supply pipe 232b through which a hydrogen-containing gas is supplied and a downstream end of an inert gas supply pipe 232c through which an inert gas is supplied are connected to the gas inlet port 234 through a confluence pipe 232. Hereinafter, the oxygen-containing gas supply pipe 232a may also be simply referred to as a “gas supply pipe 232a”, the hydrogen-containing gas supply pipe 232b may also be simply referred to as a “gas supply pipe 232b”, and the inert gas supply pipe 232c may also be simply referred to as a “gas supply pipe 232c”.

n oxygen-containing gas supply source 250a, a mass flow controller (MFC) 252a serving as a flow rate controller and a valve 253a serving as an opening/closing valve are sequentially provided at the oxygen-containing gas supply pipe 232a in this order from an upstream side to a downstream side of the oxygen-containing gas supply pipe 232a in a gas flow direction.

A hydrogen-containing gas supply source 250b, an MFC 252b and a valve 253b are sequentially provided at the hydrogen-containing gas supply pipe 232b in this order from an upstream side to a downstream side of the hydrogen-containing gas supply pipe 232b in the gas flow direction.

An inert gas supply source 250c, an MFC 252c and a valve 253c are sequentially provided at the inert gas supply pipe 232c in this order from an upstream side to a downstream side of the inert gas supply pipe 232c in the gas flow direction.

A valve 243a is provided on a downstream side of the confluence pipe 232 where the oxygen-containing gas supply pipe 232a, the hydrogen-containing gas supply pipe 232b and the inert gas supply pipe 232c join. The confluence pipe 232 is connected to an upstream end of the gas inlet port 234. It is possible to supply the process gas (which is a mixed gas of the oxygen-containing gas, the hydrogen-containing gas and the inert gas) into the process chamber 201 via the gas supply pipes 232a, 232b and 232c by opening and closing the valves 253a, 253b, 253c and 243a while adjusting flow rates of the respective gases by the MFCs 252a, 252b and 252c.

The gas supplier (which is a gas supply structure or a gas supply system) 120 according to the present embodiments is constituted mainly by the oxygen-containing gas supply pipe 232a, the hydrogen-containing gas supply pipe 232b, the inert gas supply pipe 232c, the MFCs 252a, 252b and 252c, the valves 253a, 253b and 253c and the valve 243a.

### <Exhauster>

A gas exhaust port 235 through which the process gas such as the reactive gas in the process chamber 201 is exhausted is provided on the side wall of the lower vessel 211. An upstream end of a gas exhaust pipe 231 is connected to the gas exhaust port 235. An APC (Automatic Pressure Controller) 242 serving as a pressure regulator (which is a pressure adjusting structure), a valve 243b serving as an opening/closing valve and a vacuum pump 246 serving as a vacuum exhaust apparatus are sequentially provided at the gas exhaust pipe 231 in this order from an upstream side to a downstream side of the gas exhaust pipe 231 in the gas flow direction.

An exhauster (which is an exhaust structure or an exhaust system) according to the present embodiments is constituted mainly by the gas exhaust port 235, the gas exhaust pipe 231, the APC 242 and the valve 243b. The exhauster may further include the vacuum pump 246.

### <Plasma Generator>

The resonance coil 212 of a helical shape is provided around an outer periphery of the process chamber 201 (that is, around an outer portion of the side wall 210a of the upper vessel 210) so as to surround the process chamber 201. In other words, the resonance coil 212 is arranged so as to surround an outer circumference of a portion (region) of the process vessel 203 (that is, an outer circumference of the portion of the upper vessel 210) corresponding to the plasma generation space 201a. That is, the resonance coil 212 is arranged so as to surround an outer circumference of the plasma generation chamber.

An RF (Radio Frequency) sensor 272, a high frequency power supply 273 and a matcher 274 capable of performing an impedance matching operation or an output frequency matching operation for the high frequency power supply 273 are connected to the resonance coil 212. The resonance coil 212 extends along an outer peripheral surface of the process vessel 203 while spaced apart from the outer peripheral surface of the process vessel 203, and is configured to generate an electromagnetic field in the process vessel 203 when a high frequency power (RF power) is supplied to the resonance coil 212. That is, the resonance coil 212 according to the present embodiments may be constituted by an inductively coupled plasma (ICP) type electrode.

The high frequency power supply 273 is configured to supply the high frequency power (RF power) to the resonance coil 212. The RF sensor 272 is provided at an output side of the high frequency power supply 273. The RF sensor 272 is configured to monitor information of a traveling wave or reflected wave of the supplied high frequency power. The reflected wave of the RF power monitored by the RF sensor 272 is input to the matcher 274, and the matcher 274 is configured to adjust an impedance of the high frequency power supply 273 or a frequency of the RF power output from the high frequency power supply 273 so as to minimize the reflected wave based on the information of the reflected wave inputted from the RF sensor 272.

A winding diameter, a winding pitch and the number of winding turns of the resonance coil 212 are set such that the resonance coil 212 resonates at a constant wavelength to form a standing wave of a predetermined wavelength. That is, an electrical length of the resonance coil 212 is set to an integral multiple of a wavelength of a predetermined frequency of the high frequency power supplied from the high frequency power supply 273.

Further, both ends of the resonance coil 212 are electrically grounded. At least one end of the resonance coil 212 is grounded via a movable tap 213, and the other end of the resonance coil 212 is grounded via a fixed ground 214. Further, a position of the movable tap 213 may be adjusted in order for the resonance characteristics of the resonance coil 212 to become approximately the same as those of the high frequency power supply 273. In addition, in order to fine-tune the impedance of the resonance coil 212, a power feeder (not shown) is constituted by a movable tap 215 between the grounded ends of the resonance coil 212.

A shield plate 223 is provided as a shield against an electric field outside the resonance coil 212. The shield plate 223 is of a cylindrical shape, and is made of a conductive material such as an aluminum alloy.

The plasma generator (which is a plasma generating structure) according to the present embodiments is constituted mainly by the resonance coil 212, the RF sensor 272 and the matcher 274. The plasma generator may further include the high frequency power supply 273.

Hereinafter, a principle of generating the plasma in the substrate processing apparatus 100 according to the present embodiments and properties of the generated plasma will be described with reference to FIG. 2.

A plasma generation circuit constituted by the resonance coil 212 is configured as an RLC parallel resonance circuit. When the plasma is generated in the plasma generation circuit, an actual resonance frequency may fluctuate slightly depending on conditions such as a variation (change) in a capacitive coupling between a voltage portion of the resonance coil 212 and the plasma, a variation in an inductive coupling between the plasma generation space 201a and the plasma and an excitation state of the plasma.

Therefore, according to the present embodiments, in order to compensate for a resonance shift in the resonance coil 212 (which occurs when the plasma is generated) by adjusting the power supplied from the high frequency power supply 273, the RF sensor 272 is configured to be capable of detecting the power of the reflected wave from the resonance coil 212 when the plasma is generated, and the matcher 274 is configured to be capable of correcting the output of the high frequency power supply 273 based on the detected power of the reflected wave.

Specifically, the matcher 274 is configured to increase or decrease the impedance or the output frequency of the high frequency power supply 273 such that the power of the reflected wave is minimized based on the power of the reflected wave from the resonance coil 212 detected by the RF sensor 272 when the plasma is generated.

With such a configuration, as shown in FIG. 2, the high frequency power in accordance with the actual resonance frequency of the resonance coil 212 combined with the plasma is supplied to the resonance coil 212 (or the high frequency power is supplied to match an actual impedance of the resonance coil 212 combined with the plasma). Therefore, the standing wave in which the phase voltage thereof and the opposite phase voltage thereof are always canceled out by each other is generated in the resonance coil 212. When the electrical length of the resonance coil 212 and the wavelength of the high frequency power are the same, the highest phase current is generated at an electric midpoint of the resonance coil 212 (that is, a node with zero voltage). Therefore, a donut-shaped induction plasma whose electric potential is extremely low is generated in the vicinity of the electric midpoint of the resonance coil 212. The donut-shaped induction plasma is hardly capacitively coupled with walls of the process chamber 201 or the susceptor 217.

The present embodiments are described by way of an example in which the ICP type electrode is used as the resonance coil 212 to generate the electromagnetic field in the process chamber 201 (that is, in the plasma generation space 201a). However, the technique of the present disclosure is not limited thereto. For example, a modified magnetron type (MMT) type electrode of a cylindrical shape may be used as the resonance coil 212.

### <Controller>

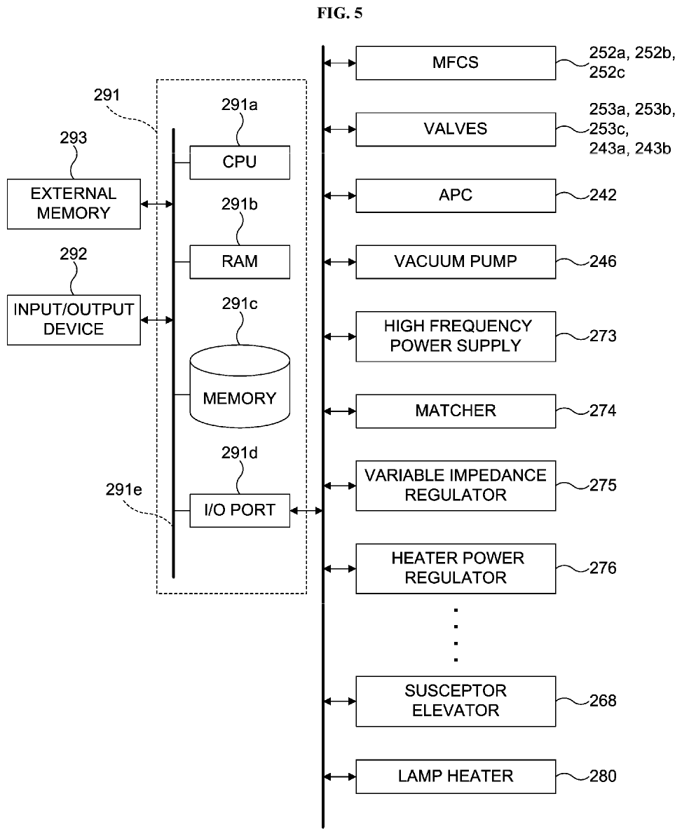

As shown in FIG. 5, the controller 291 serving as a control structure (control apparatus) is constituted by a computer including a CPU (Central Processing Unit) 291a, a RAM (Random Access Memory) 291b, a memory 291c and an I/O port 291d. The RAM 291b, the memory 291c and the I/O port 291d may exchange data with the CPU 291a through an internal bus 291e. For example, an input/output device 292 constituted by components such as a touch panel and a display is connected to the controller 291.

The memory 291c may be embodied by a component such as a flash memory and a hard disk drive (HDD). For example, a control program configured to control operations of the substrate processing apparatus 100 and a process recipe in which information such as sequences and conditions of a substrate processing described later is stored may be readably stored in the memory 291c. The process recipe is obtained by combining steps of the substrate processing described later such that the controller 291 can execute the steps to acquire a predetermined result, and functions as a program. Hereinafter, the process recipe and the control program may be collectively or individually referred to as a “program”. Thus, in the present specification, the term “program” may refer to the process recipe alone, may refer to the control program alone, or may refer to both of the process recipe and the control program. Further, the RAM 291b functions as a memory area (work area) where a program or data read by the CPU 291a is temporarily stored.

The I/O port 291d is electrically connected to the components described above such as the MFCs 252a, 252b and 252c, the valves 253a, 253b and 253c, the valves 243a and 243b, the gate valve 244, the APC 242, the vacuum pump 246, the RF sensor 272, the high frequency power supply 273, the matcher 274, the susceptor elevator 268, the variable impedance regulator 275 and a heater power regulator 276.

The CPU 291a is configured to read and execute the control program stored in the memory 291c, and to read the process recipe stored in the memory 291c in accordance with an instruction such as an operation command inputted via the input/output device 292. The CPU 291a is configured to control the operations of the substrate processing apparatus 100 in accordance with the read process recipe. For example, the CPU 291a is configured to be capable of controlling various operations, in accordance with the process recipe, such as an operation of adjusting an opening degree of the APC 242, an opening and closing operation of the valve 243b and a start and stop of the vacuum pump 246 via the I/O port 291d and a signal line “A”. Further, the CPU 291a is configured to be capable of controlling various operations, in accordance with the process recipe, such as an elevating and lowering operation of the susceptor elevator 268 via the I/O port 291d and a signal line “B”. Further, the CPU 291a is configured to be capable of controlling various operations, in accordance with the process recipe, such as a power supply amount adjusting operation (temperature adjusting operation) to the susceptor heater 217b by the heater power regulator 276 and an impedance value adjusting operation by the variable impedance regulator 275 via the I/O port 291d and a signal line “C”. Further, the CPU 291a is configured to be capable of controlling various operations, in accordance with the process recipe, such as an opening and closing operation of the gate valve 244 via the I/O port 291d and a signal line “D”. Further, the CPU 291a is configured to be capable of controlling various operations, in accordance with the process recipe, such as a controlling operation of the RF sensor 272, the matcher 274 and the high frequency power supply 273 via the I/O port 291d and a signal line “E”. Further, the CPU 291a is configured to be capable of controlling various operations, in accordance with the process recipe, such as flow rate adjusting operations for various gases by the MFCs 252a, 252b and 252c and opening and closing operations of the valves 253a, 253b, 253c and 243a via the I/O port 291d and the signal line “F”. Further, the CPU 291a may also control an operation of each component constituting the substrate processing apparatus 100 other than those described above.

The controller 291 may be embodied by installing the above-described program stored in an external memory 293 into a computer. For example, the external memory 293 may include a magnetic tape, a magnetic disk such as a flexible disk and a hard disk, an optical disk such as a CD and a DVD, a magneto-optical disk such as an MO and a semiconductor memory such as a USB memory and a memory card. The memory 291c or the external memory 293 may be embodied by a non-transitory computer readable recording medium. Hereafter, the memory 291c and the external memory 293 may be collectively or individually referred to as a “recording medium”. Thus, in the present specification, the term “recording medium” may indicate the memory 291c alone, may indicate the external memory 293 alone, and may indicate both of the memory 291c and the external memory 293. The program may be provided to the computer without using the external memory 293. For example, the program may be supplied to the computer using a communication structure such as the Internet and a dedicated line.

### (2) Substrate Processing

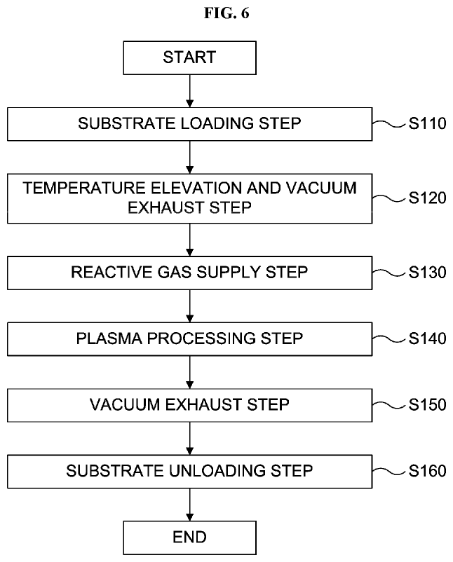

Subsequently, the substrate processing according to the present embodiments will be described mainly with reference to FIG. 6. FIG. 6 is a flow chart schematically illustrating the substrate processing according to the present embodiments. The substrate processing according to the present embodiments, which is a part of a manufacturing process of a semiconductor device (a method of manufacturing a semiconductor device) such as a flash memory, is performed by using the substrate processing apparatus 100 described above. In the following descriptions, the operations of components constituting the substrate processing apparatus 100 are controlled by the controller 291.

In addition, a silicon layer is formed in advance on the surface of the substrate 200 to be processed in the substrate processing according to the present embodiments. In the present embodiments, for example, the oxidation process serving as a process using the plasma is performed on the silicon layer.

### <Substrate Loading Step S110>

First, the susceptor 217 is lowered to a position of transferring the substrate 200 by the susceptor elevator 268 such that the substrate lift pins 266 pass through the through-holes 217a of the susceptor 217. Subsequently, the gate valve 244 is opened, and the substrate 200 is transferred (loaded) into the process chamber 201 by using a substrate transfer device (not shown) from a vacuum transfer chamber (not shown) provided adjacent to the process chamber 201. The substrate 200 loaded into the process chamber 201 is supported in a horizontal orientation by the substrate lift pins 266 protruding from a surface of the susceptor 217. Thereafter, the susceptor elevator 268 elevates the susceptor 217 until the substrate 200 is placed on an upper surface of the susceptor 217 and supported by the susceptor 217.

### <Temperature Elevation and Vacuum Exhaust Step S120>

Subsequently, a temperature of the substrate 200 loaded into the process chamber 201 is elevated. In the step S120, the susceptor heater 217b is heated in advance, and by turning on the lamp heater 280, for example, the substrate 200 placed on the susceptor 217 is heated to a predetermined temperature within a range from 700° C. to 900° C. In the step S120, for example, the substrate 200 is heated such that the temperature of the substrate 200 reaches and is maintained at 850° C. In the step S120, the light emitted (or radiated) from the lamp heater 280 that heats the substrate 200 is mostly reflected into the process chamber 201 without being absorbed by the upper vessel 210, and is absorbed by the substrate 200, as will be described later. Thereby, it is possible to efficiently heat the substrate 200 by the heat reflected into the process chamber 201. Further, while the substrate 200 is being heated, the vacuum pump 246 vacuum-exhausts an inner atmosphere of the process chamber 201 through the gas exhaust pipe 231 such that an inner pressure of the process chamber 201 reaches and is maintained at a predetermined pressure. The vacuum pump 246 vacuum-exhausts the inner atmosphere of the process chamber 201 at least until a substrate unloading step S160 described later is completed.

### <Reactive Gas Supply Step S130>

Subsequently, the oxygen-containing gas and the hydrogen-containing gas are supplied into the process chamber 201 as the reactive gas. Specifically, the valves 253a and 253b are opened to supply the oxygen-containing gas and the hydrogen-containing gas, respectively, into the process chamber 201 while the flow rates of the oxygen-containing gas and the hydrogen-containing gas are adjusted by the MFCs 252a and 252b, respectively.

In the reactive gas supply step S130, the inner atmosphere of the process chamber 201 is exhausted by adjusting the opening degree of the APC 242 such that the inner pressure of the process chamber 201 reaches and is maintained at a predetermined value (pressure). The oxygen-containing gas and the hydrogen-containing gas are continuously supplied into the process chamber 201 while the inner atmosphere of the process chamber 201 is appropriately exhausted until a plasma processing step S140 described later is completed.

For example, as the oxygen-containing gas, a gas such as oxygen (O2) gas, nitrogen peroxide (N2O) gas, nitrogen monoxide (NO) gas, nitrogen dioxide (NO2) gas, ozone (O3) gas, water vapor (H2O gas), carbon monoxide (CO) gas and carbon dioxide (CO2) gas may be used. In addition, one or more of the gases described above may be used as the oxygen-containing gas.

Further, for example, as the hydrogen-containing gas, a gas such as hydrogen (H2) gas, deuterium (D2) gas, the H2O gas and ammonia (NH3) gas may be used. In addition, one or more of the gases described above may be used as the hydrogen-containing gas. When the H2O gas is used as the oxygen-containing gas, it is preferable that a gas other than the H2O gas is used as the hydrogen-containing gas. In addition, when the H2O gas is used as the hydrogen-containing gas, it is preferable that a gas other than the H2O gas is used as the oxygen-containing gas.

For example, as the inert gas, nitrogen (N2) gas may be used. In addition, a rare gas such as argon (Ar) gas, helium (He) gas, neon (Ne) gas and xenon (Xe) gas may be used as the inert gas. For example, one or more of the gases described above may be used as the inert gas.

When the inner pressure of the process chamber 201 is stabilized, the high frequency power is supplied to the resonance coil 212 from the high frequency power supply 273. Thereby, a high frequency electric field is formed in the plasma generation space 201a to which the oxygen-containing gas and the hydrogen-containing gas are supplied, and the donut-shaped induction plasma whose plasma density is the highest is excited by the high frequency electric field at a height corresponding to the electric midpoint of the resonance coil 212 in the plasma generation space 201a. The process gas containing the oxygen-containing gas and the hydrogen-containing gas is plasma excited and dissociates. As a result, reactive species such as oxygen radicals containing oxygen (oxygen active species), oxygen ions, hydrogen radicals containing hydrogen (hydrogen active species) and hydrogen ions may be generated.

The radicals generated by the induction plasma and non-accelerated ions are uniformly supplied onto the surface of the substrate 200 placed on the susceptor 217 in the substrate processing space 201b. Then, the radicals and the ions uniformly supplied onto the surface of the substrate 200 react with the silicon layer formed on the surface of the substrate 200. Thereby, the silicon layer is modified into an oxide layer (for example, a silicon oxide layer) whose step coverage is good.

After a predetermined process time (for example, 10 seconds to 300 seconds) has elapsed, a supply of the high frequency power from the high frequency power supply 273 is stopped to stop a plasma discharge in the process chamber 201. In addition, the valves 253a and 253b are closed to stop a supply of the oxygen-containing gas and a supply of the hydrogen-containing gas into the process chamber 201. Thereby, the plasma processing step S140 is completed.

### <Vacuum Exhaust Step S150>

After the supply of the oxygen-containing gas and the supply of the hydrogen-containing gas are stopped, the inner atmosphere of the process chamber 201 is vacuum-exhausted through the gas exhaust pipe 231. Thereby, the gas such as the oxygen-containing gas, the hydrogen-containing gas and an exhaust gas generated from a reaction therebetween in the process chamber 201 is exhausted to an outside of the process chamber 201. Thereafter, the opening degree of the APC valve 242 is adjusted such that the inner pressure of the process chamber 201 is adjusted to substantially the same pressure as that of the vacuum transfer chamber (not shown) provided adjacent to the process chamber 201. Further, the vacuum transfer chamber serves as an unloading destination of the substrate 200.

### <Substrate Unloading Step S160>

After the inner pressure of the process chamber 201 is adjusted to a predetermined pressure, the susceptor 217 is lowered to the position of transferring the substrate 200 until the substrate 200 is supported by the substrate lift pins 266. Then, the gate valve 244 is opened, and the substrate 200 is transferred (unloaded) out of the process chamber 201 by using the substrate transfer device (not shown). Thereby, the substrate processing according to the present embodiments is completed.

According to the presents embodiments described above, since the upper vessel 210 includes the portion made of the opaque quartz, it is possible to reflect the light emitted from the lamp heater 280 so as to confine the light inside the process vessel 203. It is also possible to increase a density of the light irradiated to the substrate 200. Thereby, it is possible to efficiently heat the substrate 200. In other words, it is possible to obtain effects such as an effect of elevating the temperature of the substrate 200, an effect of improving a rate of elevating the temperature of the substrate 200 and an effect of saving energy. As described above, according to the presents embodiments, since the upper vessel 210 includes the portion made of the opaque quartz, it is possible to efficiently heat the substrate 200 with the light emitted from the lamp heater 280 even when a reflective material serving as a reflector is not provided between the upper vessel 210 and the resonance coil 212.

In addition, it is also conceivable to reflect the light emitted from the lamp heater 280 into the process vessel 203 by performing a coating process such as a silica coat on the inner surface of the upper vessel 210 constituting the process vessel 203 such that the light is diffusely reflected on the inner surface coated by the coating process. However, when an inner surface of the process vessel 203 (that is, the inner surface of the upper vessel 210) is etched due to an influence of an the electromagnetic field or the like for generating the plasma in the process vessel 203, particles are relatively easily generated by performing the coating process such as the silica coat. On the other hand, according to the present embodiments, at least a part of the upper vessel 210 is made of the opaque quartz. Thus, even when the inner surface of the upper vessel 210 is etched due to the influence of the electromagnetic field or the like, it is possible to prevent or to reduce the particles from being generated.

According to the presents embodiments, at least a portion of the process vessel 203 (that is, the upper vessel 210), which corresponds to a range from an upper end to a lower end of the plasma generator (that is, the range from the upper end to the lower end of the resonance coil 212), is made of the opaque quartz. As a result, it is possible to prevent the light emitted from the lamp heater 280 from directly irradiating the plasma generator including the resonance coil 212. Thereby, it is possible to suppress a damage and a deterioration of the plasma generator due to the heat.

Further, according to the present embodiments, the controller 291 is configured to be capable of controlling the susceptor elevator 268 such that the substrate 200 is located below the range from the upper end to the lower end of the plasma generator when the substrate 200 is processed. Thereby, even when the substrate 200 is spaced apart from the lamp heater 280 via the plasma generation region, it is possible to efficiently heat the substrate 200 with the light (radiant light) emitted from the lamp heater 280 and reflected by the opaque quartz constituting the upper vessel 210.

As described above, at least a portion of the upper vessel 210, which corresponds to the range from the upper end to the lower end of the plasma generator (that is, a portion corresponding to the plasma generation space 201a), is made of the opaque quartz. A thickness T of the portion described above may be set to 2 mm or more and 20 mm or less, more preferably, 2 mm or more and 10 mm or less (see FIG. 1). When the thickness T is 2 mm or more, it is possible to reflect the radiant light of the lamp heater 280 within the process vessel 203 (that is, the upper vessel 210) without substantially transmitting the light to the outside of the process vessel 203. However, when the thickness T is less than 2 mm, a part of the radiant light may be substantially transmitted to the outside of the process vessel 203. Moreover, when the thickness T is greater than 20 mm, most of the energy of the electromagnetic field generated by the resonance coil 212 may be converted into the heat in the opaque quartz and may become a loss. Therefore, from the viewpoint of an energy efficiency and a suppression of a temperature elevation of the upper vessel 210, it is preferable that the thickness T is 20 mm or less. Furthermore, by setting the thickness T to 10 mm or less, it is possible to more reliably obtain the effects of improving the energy efficiency and suppressing the temperature elevation of the upper vessel 210.

According to the present embodiments, at least a part of the flange 210d is made of the opaque quartz. Thereby, it is possible to prevent the O-ring 301 from being heated by being directly irradiated with the radiant light of the lamp heater 280. In addition, it is possible to prevent the O-ring 301 from being indirectly heated by a temperature elevation of the flange 210d due to the radiant light of the lamp heater 280. In particular, when the joint surface 210d1 of the flange 210d attached to the manifold 300 is made of the opaque quartz, it is possible to prevent the O-ring 301 from being heated by being directly irradiated with the radiant light of the lamp heater 280.

Further, according to the present embodiments, at least a part of the ceiling 210b is made of the opaque quartz. Thereby, it is possible to prevent the O-ring 303 from being indirectly heated due to a temperature elevation of the upper vessel 210 by the radiant light of the lamp heater 280. In particular, when the joint surface 210b1 of the ceiling 210b attached to the manifold 302 is made of the opaque quartz, it is possible to prevent the O-ring 303 from being indirectly heated by the radiant light of the lamp heater 280.

According to the present embodiments, the lamp heater 280 is capable of emitting the light of peak wavelength of 5 μm or less. According to the present embodiments, by using a heater (a lamp heater or the like) capable of emitting the light in a wavelength range of peak wavelength of 5 μm or less as the lamp heater 280, it is possible to reflect most of the radiant light by the opaque quartz. Thereby, it is possible to efficiently heat the substrate 200. On the other hand, when the lamp heater 280 is replaced with a resistance heater or the like that mainly emits (or radiates) a light (such as an infrared light) in a wavelength region with a wavelength exceeding 5 μm, a ratio of the radiation light reflected by the opaque quartz may be small. Thereby, it may be difficult to effectively heat the substrate 200 by the reflected light. Further, when the heater (the lamp heater or the like) capable of emitting the light in a wavelength range whose peak wavelength is 3 μm or less is used as the lamp heater 280, it is possible to further increase the reflectance of the radiation light reflected by the opaque quartz. Thereby, it is possible to more efficiently heat the substrate 200.

Further, the opaque quartz used in the present embodiments is capable of reflecting 50% or more of the light within a predetermined wavelength range lower than or equal to 5 When transparent quartz is used, it is difficult to reflect 50% or more of the light in the predetermined wavelength range. According to the present embodiments, by reflecting 50% or more, preferably 70% or more, more preferably 80% or more of the light in the predetermined wavelength range by the opaque quartz, it is possible to efficiently apply the energy of the irradiated light to the substrate 200. When the reflectance is less than 50%, since 50% or more of the irradiated light in the predetermined wavelength range is transmitted through the upper vessel 210 or is absorbed by the upper vessel 210, most of the energy of the irradiated light is transmitted to the outside of the upper vessel 210. As a result, it may be difficult to efficiently heat the substrate 200 by the energy of the light irradiated from the lamp heater 280. When most of the energy of the irradiated light is transmitted to the outside of the upper vessel 210 as described above, a component provided outside the upper vessel 210 may be heated by the transmitted (or emitted) light, and the component provided outside the upper vessel 210 may easily deteriorate, or defects may easily occur in the component provided outside the upper vessel 210. The wavelength range of the light in which 50% or more of the energy is reflected by the opaque quartz used in the present embodiments preferably includes at least the peak wavelength of the light emitted from the lamp heater 280, and more preferably includes a wavelength range from the peak wavelength to a wavelength at which the energy is halved, which is centered around the peak wavelength. For example, by using the opaque quartz whose reflectance of the light is 50% or more in a wavelength range of 0.5 μm to 5 μm and by using the lamp heater 280 capable of emitting the light in the wavelength range whose peak wavelength is 3 μm or less, it is possible to particularly efficiently the irradiated light. Thereby, it is possible to efficiently heat the substrate 200. In a wavelength range of less than 0.5 μm, a ratio of absorbing the light by the opaque quartz may increase. Thereby, a desired reflectance may not be obtained.

Further, it is preferable that the opaque quartz used in the present embodiments contains air bubbles with an average diameter of 30 μm or less. By setting the average diameter of the air bubbles to 30 μm or less, it is possible to reflect most of the light within the wavelength range lower than or equal to 5 μm emitted from the heater (the lamp heater or the like). When the average diameter of the air bubbles is greater than 30 μm, most of the light within the wavelength range lower than or equal to 5 μm is transmitted or absorbed, and an effect of reflecting the light may be hardly obtained. When the average diameter of the air bubbles is 20 μm or less, it is possible to further enhance the effect of reflecting the light within the wavelength range lower than or equal to 5 μm. Further, when the average diameter of the air bubbles is less than 0.1 μm, most (for example, more than 50%) of the light within the wavelength range lower than or equal to 5 μm is transmitted or absorbed, for example, within a density range of the air bubbles described later, and the effect of reflecting the light may be hardly obtained. By setting the average diameter of the air bubbles to 0.1 μm or more, it is possible to reflect most (for example, 50% or more) of the light within the wavelength range lower than or equal to 5 μm, for example, in the density range of the air bubbles described later. Thereby, it is possible to enhance the effect of reflecting the light.

Further, it is preferable that the opaque quartz used in the present embodiments contains the air bubbles with a density of 1×106/cm3 or more and 1×109/cm3 or less. According to the present embodiments, by setting the density of the air bubbles contained in the opaque quartz to 1×106/cm3 or more, it is possible to reflect most (for example, 50% or more) of the light within the wavelength range lower than or equal to 5 μm emitted from the heater (the lamp heater or the like). When the density of the air bubbles is less than 1×106/cm3, most (for example, more than 50%) of the light within the wavelength range lower than or equal to 5 μm is transmitted or absorbed, and the effect of reflecting the light may be hardly obtained. Further, by setting the density of the air bubbles contained in the opaque quartz to 1×109/cm3 or less, it is possible to secure an etching resistance by the plasma, and it is also possible to maintain a mechanical strength of the upper vessel 210. When the density of the air bubbles contained in the opaque quartz is greater than 1×109/cm3, the etching resistance by the plasma may be significantly reduced, and it may be difficult to maintain the mechanical strength of the upper vessel 210. Further, by setting the density of the air bubbles contained in the opaque quartz to 1×107/cm3 or more, it is possible to further enhance the effect of reflecting the light within the wavelength range lower than or equal to 5 μm.

According to the present embodiments, the process of reducing the surface roughness is performed on the portion of the inner surface of the upper vessel 210, which is made of the opaque quartz. For example, the process of reducing the surface roughness is performed on the portion of the inner surface of the upper vessel 210 such that the surface roughness of the inner surface of the upper vessel 210 is smaller than the surface roughness of an outer peripheral surface of the upper vessel 210. Thereby, it is possible to suppress an occurrence of etching on the inner surface of the upper vessel 210 in the plasma processing, and it is also possible to reduce a generation of foreign substances (that is, the particles) due to a peeling off even when the inner surface of the upper vessel 210 is etched. For example, in a very rough surface, many sharp-angled portions formed by the air bubbles contained in the opaque quartz may be present. The sharp-angled portions may be easily peeled off due to an etching action in the plasma processing, and the quartz of the peeled off sharp-angled portions becomes the foreign substances. Thus, according to the present embodiments, the process of reducing the surface roughness is performed so as to remove the sharp-angled portions.

Further, according to the present embodiments, the joint surface 210d1 of the flange 210d attached to the manifold 300 is made of the opaque quartz, and the process of reducing the surface roughness caused by the air bubbles contained in the opaque quartz is performed on the joint surface 210d1. Thereby, it is possible to maintain a sealing surface of the O-ring 301, or it is possible to improve a sealing performance of the O-ring 301. Similarly, according to the present embodiments, the joint surface 210b1 of the ceiling 210b attached to the manifold 302 is made of the opaque quartz, and the process of reducing the surface roughness caused by the air bubbles contained in the opaque quartz is performed on the joint surface 210b1. Thereby, it is possible to maintain a sealing surface of the O-ring 303, or it is possible to improve a sealing performance of the O-ring 303.

However, it may be difficult to reduce the surface roughness of the opaque quartz containing the air bubbles by polishing. Therefore, according to the present embodiments, as the process of reducing the surface roughness, for example, the baking finish process is performed. By performing the baking finish process, it is possible to melt and remove the sharp-angled portions of the quartz caused by the air bubbles, and it is also possible to partially or completely fill concave portions caused by the air bubbles with the molten quartz. Thereby, it is possible to perform a surface smoothing. In addition, by performing the baking finish process on at least a portion of the upper vessel 210, which corresponds to the plasma generation region, it is possible to obtain an effect of suppressing the generation of the foreign substances by the surface smoothing.

### Other Embodiments of Present Disclosure

While the technique of the present disclosure is described in detail by way of the embodiments described above, the above-described technique is not limited thereto. For example, the embodiments described above are described by way of an example in which the process of reducing the surface roughness of the opaque quartz is performed with respect to the inner surface of the upper vessel 210. However, the technique of the present disclosure is not limited thereto. For example, by performing the baking finish process on an inner side surface of the portion of the inner surface of the upper vessel 210, which is made of the opaque quartz, a layer whose density of the air bubbles is low as compared with that of other portions of the opaque quartz (for example, portions of the opaque quartz on which the baking finish process is not performed), preferably, a layer without containing the air bubbles, may be formed on the inner side surface of the portion described above. By providing the layer whose density of the air bubbles is low or the layer without containing the air bubbles on the inner side surface of the portion described above, even when the inner surface of the upper vessel 210 is etched in the plasma processing, it is possible to suppress an occurrence of exposure of the air bubbles into the upper vessel 210, and it is also possible to suppress the generation of the foreign substances due to the exposure of the air bubbles. Further, by forming the layer whose density of the air bubbles is low or the layer without containing the air bubbles with respect to the plasma generation region, it is possible to obtain the effect described above obtained by reducing the surface roughness. As a method of forming the layer whose density of the air bubbles is low or the layer without containing the air bubbles, the process of reducing the surface roughness may be performed with a longer process time and/or the baking finish process may be performed with a higher process temperature.

Further, according to the other embodiments of the present disclosure, the layer whose density of the air bubbles is low or the layer without containing the air bubbles may be further provided on the joint surface 210d1 of the flange 210d attached to the manifold 300. By providing the layer whose density of the air bubbles is low or the layer without containing the air bubbles on the joint surface 210d1, it is possible to maintain the sealing surface of the O-ring 301, or it is possible to improve the sealing performance of the O-ring 301.

Further, according to the other embodiments of the present disclosure, by setting a thickness of the layer whose density of the air bubbles is low or the layer without containing the air bubbles to 100 μm or more, even when the etching by the plasma processing is performed, even when the inner surface of the upper vessel 210 is etched in the plasma processing, it is possible to suppress an exposure of a layer containing many air bubbles into the upper vessel 210, and it is also possible to reduce the generation of the foreign substances due to the exposure of the air bubbles.

In addition, similarly to the transparent quartz, the layer whose density of the air bubbles is low or the layer without containing the air bubbles contains a property of relatively easily absorbing the light in a wavelength range that is efficiently reflected by the opaque quartz described above. That is, the layer whose density of the air bubbles is low or the layer without containing the air bubbles is inferior in function as a reflective layer. Therefore, according to the other embodiments of the present disclosure, by setting the thickness of the layer whose density of the air bubbles is low or the layer without containing the air bubbles to 1,000 μm or less, it is possible to efficiently heat the substrate 200 while limiting the ratio of absorbing the energy of the light emitted from the lamp heater 280 by the layer whose density of the air bubbles is low or the layer without containing the air bubbles. It is also possible to suppress the temperature elevation of the upper vessel 210. Further, preferably, by setting the thickness of the layer whose density of the air bubbles is low or the layer without containing the air bubbles to 500 μm or less, it is possible to more remarkably obtain the effects described above. When the thickness of the layer whose density of the air bubbles is low or the layer without containing the air bubbles is greater than 1,000 μm, the ratio of absorbing the energy of the light emitted from the heater may increase, and it may become substantially difficult to heat the substrate 200 efficiently. In addition, since the temperature of the upper vessel 210 is likely to be elevated, and a component such as the O-ring may significantly deteriorate. When the thickness of the layer whose density of the air bubbles is low or the layer without containing the air bubbles is greater than 500 μm, an effect of efficiently heating the substrate 200 may be greatly reduced, and a deterioration of the O-ring may be accelerated.

For example, the embodiments described above are described by way of an example in which the baking finish process is performed with respect to the inner surface of the upper vessel 210. However, the technique of the present disclosure is not limited thereto. For example, as the process of reducing the surface roughness caused by the air bubbles contained in the opaque quartz, an etching process may be performed with respect to the inner surface of the upper vessel 210. When the etching process is performed, similar to the baking finish process, it is possible to remove the sharp-angled portions of the quartz caused by the air bubbles to perform the surface smoothing with respect to the surface of the opaque quartz. However, a concave portion may not be filled or chemicals used for the etching process (for example, hydrofluoric acid solution and the like) may remain on the surface of the opaque quartz. Thus, it is more preferable that the baking finish process is performed as the process of reducing the surface roughness.

For example, the embodiments described above are described by way of an example in which the process chamber 201 defined by the process vessel 203 includes the plasma generation chamber and the substrate processing chamber (that is, the plasma generation chamber and the substrate processing chamber are configured as an inner surface of the process vessel 203). However, the technique of the present disclosure is not limited thereto. For example, the plasma generation chamber and the substrate processing chamber may be configured as separate vessels. For example, the embodiments described above are described by way of an example in which the upper vessel 210 serves as an example of a part of the process vessel 203. However, the technique of the present disclosure is not limited thereto. For example, when the process vessel 203 is configured an integrally molded product, the integrally molded product serves as an example of the process vessel 203 in the present disclosure.

For example, the embodiments described above are described by way of an example in which the ceiling 210b of the upper vessel 210 serves as an example of a flange. However, the technique of the present disclosure is not limited thereto. For example, another flange projecting radially outward from the upper end portion of the upper vessel 210 may be provided and the manifold 302 may be attached to the above-mentioned another flange. For example, the embodiments described above are described by way of an example in which an entirety of the upper vessel 210 is made of the opaque quartz. However, the technique of the present disclosure is not limited thereto. For example, the sidewall 210a of the upper vessel 210 alone, the flange 210d alone or the ceiling 210b alone may be made of the opaque quartz, or a combination thereof may be made of the opaque quartz.

For example, the embodiments described above are described by way of an example in which the oxidation process using the plasma is performed onto the surface of the substrate. However, the technique of the present disclosure is not limited thereto. For example, a nitridation process using a nitrogen-containing gas as the process gas may be performed. Further, the technique of the present disclosure is not limited to the nitridation process and the oxidation process, and may be applied to other processing techniques of processing the substrate using the plasma. For example, the technique of the present disclosure may be applied to a process such as a modification process onto a film formed on the surface of the substrate, a doping process, a reduction process of an oxide film, an etching process with respect to the film and a photoresist ashing process, which are performed by using the plasma.

For example, the technique of the present disclosure is described by way of the embodiments and modified examples described above. However, the technique of the present disclosure is not limited thereto. It is apparent to the person skilled in the art that the technique of the present disclosure may be modified in various ways without departing from the scope thereof.

According to some embodiments of the present disclosure, it is possible to efficiently heat the substrate with the light emitted from the lamp heater.

What is claimed is:

1. A substrate processing apparatus comprising:
a process vessel at least a part of which is made of opaque quartz;
a substrate mounting table provided in the process vessel or in a processing space communicating with an inside of the process vessel;
a lamp heater provided at a position facing a substrate placing surface of the substrate mounting table; and
a plasma generator provided at an outer periphery of the process vessel and configured to excite a gas in the process vessel by a plasma.

2. The substrate processing apparatus of claim 1, wherein a portion of the process vessel corresponding to a range from an upper end to a lower end of the plasma generator is made of the opaque quartz.

3. The substrate processing apparatus of claim 2, further comprising:
a driver capable of elevating and lowering the substrate mounting table; and
a controller configured to be capable of controlling the driver such that a substrate is located below the range from the upper end to the lower end of the plasma generator while the substrate placed on the substrate placing surface is being processed.

4. The substrate processing apparatus of claim 1, further comprising
a flange provided at at least one of an upper end portion or a lower end portion of the process vessel and attached to a manifold via a seal,
wherein at least a part of the flange is made of the opaque quartz.

5. The substrate processing apparatus of claim 4, wherein a joint surface of the flange attached to the manifold is made of the opaque quartz.

6. The substrate processing apparatus of claim 1, wherein the opaque quartz is capable of reflecting 50% or more of light of peak wavelength among light emitted from the lamp heater.

7. The substrate processing apparatus of claim 1, wherein the opaque quartz is capable of reflecting 50% or more of light within a predetermined wavelength range equal to or lower than 5 μm.

8. The substrate processing apparatus of claim 1, wherein the opaque quartz contains air bubbles with an average diameter of 30 μm or less.

9. The substrate processing apparatus of claim 1, wherein the opaque quartz contains air bubbles with a density of 1×106/cm3 or more.

10. The substrate processing apparatus of claim 1, wherein a portion of the process vessel corresponding to a range from an upper end to a lower end of the plasma generator is made of the opaque quartz, and
wherein reducing a surface roughness is performed on a portion of an inner surface of the process vessel made of the opaque quartz.

11. The substrate processing apparatus of claim 10, wherein the reducing the surface roughness comprises a baking finish process.

12. The substrate processing apparatus of claim 1, further comprising
a flange provided at at least one of an upper end portion or a lower end portion of the process vessel and attached to a manifold via a seal,
wherein a joint surface of the flange attached to the manifold is made of the opaque quartz, and
wherein reducing a surface roughness is performed on the joint surface.

13. The substrate processing apparatus of claim 1, wherein a portion of the process vessel corresponding to a range from an upper end to a lower end of the plasma generator is made of the opaque quartz, and
wherein a portion of an inner surface of the process vessel made of the opaque quartz is provided with a layer whose density of air bubbles is lower than that of other portions made of the opaque quartz or a layer without containing the air bubbles.

14. The substrate processing apparatus of claim 13, wherein the layer whose density of the air bubbles is lower than that of the other portions made of the opaque quartz or the layer without containing the air bubbles is formed by performing a baking finish process.

15. The substrate processing apparatus of claim 13, wherein a thickness of the layer whose density of the air bubbles is lower than that of the other portions made of the opaque quartz or the layer without containing the air bubbles is 100 μm or more.

16. The substrate processing apparatus of claim 15, wherein the thickness of the layer whose density of the air bubbles is lower than that of the other portions made of the opaque quartz or the layer without containing the air bubbles is 1,000 μm or less.

17. The substrate processing apparatus of claim 1, further comprising
a flange provided at at least one of an upper end portion or a lower end portion of the process vessel and attached to a manifold via a seal,
wherein a joint surface of the flange attached to the manifold is made of the opaque quartz, and
wherein the joint surface is provided with a layer whose density of air bubbles is lower than that of other portions made of the opaque quartz or a layer without containing the air bubbles.

18. A method of manufacturing a semiconductor device, comprising:
(a) placing a substrate on a substrate placing surface of a substrate mounting table provided in a process vessel at least a part of which is made of opaque quartz or in a processing space communicating with an inside of the process vessel;
(b) heating the substrate with a lamp heater provided at a position facing the substrate placing surface;
(c) exciting a gas supplied into the process vessel by a plasma by a plasma generator provided at an outer periphery of the process vessel; and
(d) processing the substrate by using the gas excited by the plasma.

19. A non-transitory computer-readable recording medium storing a program that causes a substrate processing apparatus, by a computer, to perform:
(a) placing a substrate on a substrate placing surface of a substrate mounting table provided in a process vessel at least a part of which is made of opaque quartz or in a processing space communicating with an inside of the process vessel;
(b) heating the substrate with a lamp heater provided at a position facing the substrate placing surface;
(c) exciting a gas supplied into the process vessel by a plasma by a plasma generator provided at an outer periphery of the process vessel; and
(d) processing the substrate by using the gas excited by the plasma.
